(19) United States
(12) Patent Application Publication
(10) Pub. No.: US 2024/0274680 A1
(43) Pub. Date: Aug. 15, 2024

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Tomoaki INOKUCHI, Yokohama (JP); Yusuke KOBAYASHI, Yokohama (JP); Shotaro BABA, Kawasaki (JP); Hiroki NEMOTO, Nonoichi (JP); Taichi FUKUDA, Yokohama, (JP); Tatsuya NISHIWAKI, Yokohama (JP); Tatsuo SHIMIZU, Tokyo (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 18/456,786

(22) Filed: Aug. 28, 2023

(30) Foreign Application Priority Data
Feb. 14, 2023 (JP) 2023-021043

(51) Int. Cl. H01L 29/417; H01L 29/40; H01L 29/47

(52) U.S. Cl. CPC H01L 29/41741; H01L 29/401; H01L 29/47

(57) ABSTRACT

A semiconductor device includes first to third conductive portions, a first insulating portion, and a semiconductor portion. The semiconductor portion includes a first semiconductor region provided between the first conductive portion and the second conductive portion, and a second semiconductor region provided between the second conductive portion and the first insulating region. The second conductive portion includes a first conductive region in Schottky junction with the first semiconductor region, and a second conductive region in Schottky junction with the second semiconductor region. When the first conductivity-type is an n-type, a work function of the first conductive region is smaller than a work function of the second conductive region. When the first conductivity-type is a p-type, the work function of the first conductive region is larger than the work function of the second conductive region.

### CROSS-REFERENCE TO RELATED APPLICATIONS

This application is based upon and claims the benefit of priority from Japanese Patent Application No. 2023-021043, filed on Feb. 14, 2023; the entire contents of which are incorporated herein by reference.

### FIELD

Embodiments relate to a semiconductor device.

### BACKGROUND

In a semiconductor device such as a transistor, it is desirable to reduce a forward voltage of a body diode.

### BRIEF DESCRIPTION OF THE DRAWINGS

FIG. 1 is a schematic cross-sectional view illustrating a semiconductor device according to an embodiment;

FIGS. 2A and 2B are schematic cross-sectional views illustrating the semiconductor device according to the embodiment;

FIGS. 3A to 3E are schematic cross-sectional views illustrating a method for manufacturing the semiconductor device according to the embodiment;

FIGS. 4A to 4E are schematic cross-sectional views illustrating the method for manufacturing the semiconductor device according to the embodiment; and

FIGS. 5A to 5C are schematic cross-sectional views illustrating the method for manufacturing the semiconductor device according to the embodiment.

### DETAILED DESCRIPTION

A semiconductor device according to one embodiment, includes a first conductive portion, a second conductive portion, a third conductive portion, a first insulating portion, and a semiconductor portion. A direction from the first conductive portion toward the second conductive portion is along a first direction. A direction from the second conductive portion toward the third conductive portion is along a second direction that intersects the first direction. The first insulating portion includes a first insulating region provided between the second conductive portion and the third conductive portion. The semiconductor portion being of a first conductivity-type. The semiconductor portion includes a first semiconductor region and a second semiconductor region. The first semiconductor region is provided between the first conductive portion and the second conductive portion. The second semiconductor region is provided between the second conductive portion and the first insulating region. The second conductive portion includes a first conductive region in Schottky junction with the first semiconductor region, and a second conductive region in Schottky junction with the second semiconductor region. When the first conductivity-type is an n-type, a work function of the first conductive region is smaller than a work function of the second conductive region. When the first conductivity-type is a p-type, the work function of the first conductive region is larger than the work function of the second conductive region.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

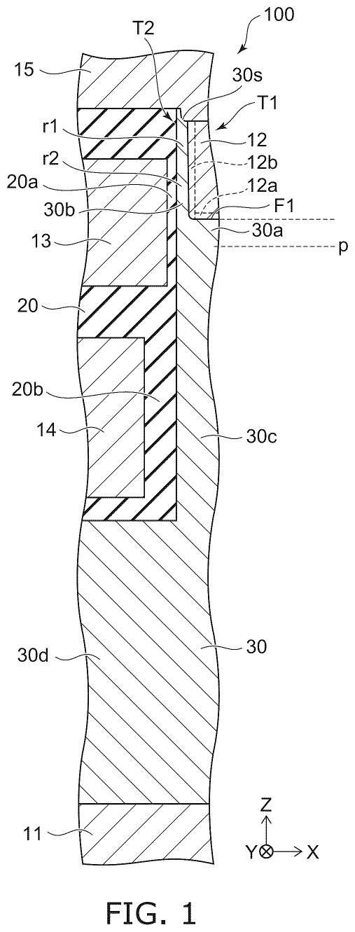

FIG. 1 is a schematic cross-sectional view illustrating a semiconductor device according to an embodiment.

As shown in FIG. 1, a semiconductor device 100 according to the embodiment includes a first conductive portion 11, a second conductive portion 12, a third conductive portion 13, an insulating portion 20, and a semiconductor portion 30. The semiconductor device 100 may further include a fourth conductive portion 14 and a fifth conductive portion 15.

A direction from the first conductive portion 11 toward the second conductive portion 12 is along a first direction. The first direction is taken as a Z-axis direction. One direction perpendicular to the Z-axis direction is taken as an X-axis direction. A direction perpendicular to the Z-axis direction and the X-axis direction is taken as a Y-axis direction.

A direction from the first conductive portion 11 toward the semiconductor portion 30 is along the first direction. The semiconductor portion 30 includes a first semiconductor region 30a, a second semiconductor region 30b, a third semiconductor region 30c, and a fourth semiconductor region 30d. The semiconductor portion 30 is of a first conductivity-type (for example, an n-type). In this example, the first conductivity-type is the n-type and a second conductivity-type is a p-type.

Alternatively, in the embodiment, the first conductivity-type may be the p-type and the second conductivity-type may be the n-type.

The first semiconductor region 30a is provided between the first conductive portion 11 and the second conductive portion 12. A direction from the first semiconductor region 30a toward the second conductive portion 12 is along the first direction. The first semiconductor region 30a is in contact with the second conductive portion 12.

A direction from the second semiconductor region 30b toward the second conductive portion 12 is along a second direction (for example, the X-axis direction). The second semiconductor region 30b is in contact with the second conductive portion 12. The second semiconductor region 30b is provided between the first semiconductor region 30a and the fifth conductive portion 15.

For example, a trench T1 is provided in a surface 30s of the semiconductor portion 30. The trench T1 extends, for example, in a third direction. Multiple trenches T1 may be provided at intervals in the second direction. The second conductive portion 12 is provided in the trench T1. The second conductive portion 12 is a trench contact electrically connected to the semiconductor portion 30. For example, the first semiconductor region 30a forms a bottom surface of the trench T1. For example, the second semiconductor region 30b forms a side surface of the trench T1.

The third semiconductor region 30c is provided between the first conductive portion 11 and the first semiconductor region 30a. The fourth semiconductor region 30d is provided between the first conductive portion 11 and the third conductive portion 13. The fourth semiconductor region 30d is provided between the third semiconductor region 30c and the first conductive portion 11.

A direction from the second conductive portion 12 toward the third conductive portion 13 is along the second direction (for example, the X-axis direction). The second direction is a direction that intersects the first direction.

A direction from the fourth conductive portion 14 toward the third semiconductor region 30c is along the second direction (for example, the X-axis direction). In this example, a direction from the fourth conductive portion 14 toward the third conductive portion 13 is along the first direction. The fourth conductive portion 14 is provided between the third conductive portion 13 and the first conductive portion 11. The fourth semiconductor region 30d is provided between the fourth conductive portion 14 and the first conductive portion 11.

The insulating portion 20 is in contact with the third conductive portion 13, the fourth conductive portion 14, and the semiconductor portion 30. The insulating portion 20 electrically insulates the third conductive portion 13 from the semiconductor portion 30. The insulating portion 20 electrically insulates the fourth conductive portion 14 from the semiconductor portion 30. The insulating portion 20 electrically insulates the third conductive portion 13 from the fourth conductive portion 14.

More specifically, the insulating portion 20 includes a first insulating region 20a provided between the second conductive portion 12 and the third conductive portion 13. The second semiconductor region 30b is provided between the second conductive portion 12 and the first insulating region 20a. The insulating portion 20 further includes, for example, a second insulating region 20b provided between the third semiconductor region 30c and the fourth conductive portion 14. The insulating portion 20 further includes, for example, a portion provided between the fourth semiconductor region 30d and the fourth conductive portion 14, a portion provided between the fourth conductive portion 14 and the third conductive portion 13, and a portion provided between the third conductive portion 13 and the fifth conductive portion 15.

For example, a trench T2 is provided in the surface 30s of the semiconductor portion 30. The trench T2 extends, for example, in the third direction. Multiple trenches T2 may be provided at intervals in the second direction. The insulating portion 20 is provided in the trench T2. The third conductive portion 13 and the fourth conductive portion 14 are surrounded by the insulating portion 20 in the trench T2.

The second conductive portion 12 or the third conductive portion 13 is provided between the fifth conductive portion 15 and the first conductive portion 11. The fifth conductive portion 15 is in contact with the second conductive portion 12 and the insulating portion 20. The fifth conductive portion 15 is electrically connected to the second conductive portion 12.

The second conductive portion 12 includes a first conductive region 12a in Schottky junction with the first semiconductor region 30a, and a second conductive region 12b in Schottky junction with the second semiconductor region 30b. In the example in which the first conductivity-type is the n-type, a work function of the first conductive region 12a is smaller than a work function of the second conductive region 12b.

That is, for example, the first conductive region 12a is in Schottky contact with the bottom surface of the trench T1 (first semiconductor region 30a). The first conductive region 12a faces and is in contact with the first semiconductor region 30a in the first direction (Z-axis direction). For example, the second conductive region 12b is in Schottky contact with the side surface of the trench T1 (second semiconductor region 30b). The second conductive region 12b faces and is in contact with the second semiconductor region 30b in the second direction (X-axis direction).

The first semiconductor region 30a includes a facing surface F1 that faces the second conductive portion 12 (first conductive region 12a). A direction from the third conductive portion 13 toward the facing surface F1 is along the second direction (for example, the X-axis direction).

The second semiconductor region 30b may include a first region r1 and a second region r2. The second region r2 is provided between the first region r1 and the first conductive portion 11. A concentration (atoms/cm³) of an impurity of the first conductivity-type in the first region r1 is larger than a concentration of an impurity of the first conductivity-type in the second region r2.

The semiconductor device 100 is, for example, a metal oxide silicon field effect transistor (MOSFET). By controlling a potential of the third conductive portion 13, a current flowing between the first conductive portion 11 and the second conductive portion 12 (and the fifth conductive portion 15) can be controlled. The first conductive portion 11 functions as, for example, a drain electrode. The second conductive portion 12 (and the fifth conductive portion 15) functions as, for example, a source electrode. The first region r1 functions as, for example, a source region. The second region r2 functions as, for example, a channel region. The third conductive portion 13 functions as, for example, a gate electrode. The first insulating region 20a functions as, for example, a gate insulating film.

For example, a Schottky barrier is formed at an interface between the second conductive portion 12 (second conductive region 12b) and the second semiconductor region 30b, and a depletion layer is formed in the second semiconductor region 30b (second region r2). By the potential of the third conductive portion 13, a thickness (a distance in the X-axis direction) of the Schottky barrier is controlled, and a carrier concentration in the second semiconductor region 30b (second region r2) is controlled. When the carrier concentration in the second semiconductor region 30b is small, no current substantially flows between the second conductive portion 12 (and the fifth conductive portion 15) and the first conductive portion 11 via the second semiconductor region 30b. That is, an OFF state is obtained. When the carrier concentration in the second semiconductor region 30b is increased by controlling the potential of the third conductive portion 13, the current flows between the second conductive portion 12 (and the fifth conductive portion 15) and the first conductive portion 11 via the second semiconductor region 30b. That is, an ON state is obtained.

For example, a Schottky barrier is formed at an interface between the first conductive region 12a and the first semiconductor region 30a. By the potential of the third conductive portion 13, a thickness (a distance in the Z-axis direction) of the Schottky barrier can be controlled. When the Schottky barrier has a large thickness, a current is difficult to flow. For example, an OFF state is obtained. By controlling the potential of the third conductive portion 13, the thickness of the Schottky barrier is decreased and a tunnel current easily flows. For example, an ON state is obtained.

For example, there is a transistor having an npn structure of a reference example. In this case, a gate length increases according to a width of p-n junction. In contrast, in the embodiment, the semiconductor portion 30 is of the first conductivity-type and may not include a region of the second conductivity-type. That is, no p-n junction is formed. Accordingly, for example, the gate length is easily decreased. Therefore, a gate capacity is easily reduced. In addition, for example, on-resistance is easily reduced. It is possible to increase a switching speed, prevent a turn-on loss, and prevent a turn-off loss. According to the embodiment, it is possible to provide a semiconductor device in which characteristics can be improved.

In the transistor of the reference example, a body diode is implemented by p-n junction. Therefore, recovery may take a long time. In contrast, in the embodiment, the Schottky barrier is formed at the interface between the second conductive portion 12 (first conductive region 12a) and the first semiconductor region 30a. Accordingly, the body diode is formed. Since such a body diode is a Schottky diode, recovery characteristics can be improved. A recovery speed can be increased.

As described above, in this example, the first conductivity-type is the n-type. That is, the first semiconductor region 30a is an n-type semiconductor. When the first conductivity-type is the n-type in this manner, the work function of the first conductive region 12a is smaller than, for example, the work function of the second conductive region 12b. Since the work function of the first conductive region 12a is relatively small, a height of the Schottky barrier at the interface between the first conductive region 12a and the first semiconductor region 30a can be reduced. Accordingly, a forward voltage VF of the body diode can be reduced. It is possible to reduce a power loss in diode conduction in which a current flows from the second conductive portion 12 to the semiconductor portion 30.

On the other hand, since the work function of the second conductive region 12b is relatively large, a height of the Schottky barrier at the interface between the second conductive region 12b and the second semiconductor region 30b is controlled, and a threshold of the transistor can be adjusted. For example, the threshold can be prevented from being excessively small.

For example, the first conductive region 12a is made of a metal having a work function smaller than that of the second conductive region 12b. For example, the second conductive region 12b is made of a metal having a work function larger than that of the first conductive region 12a.

For example, the first conductive region 12a contains a first metal element, and the second conductive region 12b contains a second metal element. The work function of the first conductive region 12a is smaller than the work function of the second conductive region 12b. A work function of a first metal formed of the first metal element is smaller than a work function of a second metal formed of the second metal element.

In this example, the work function of the first conductive region 12a (for example, the work function of the first metal) can be set to 0.5 electron volts (eV) or more and 4.8 eV or less. More specifically, the first metal element includes, for example, at least one selected from the group consisting of Al, Mg, Ti, Se, V, Cr, Mn, Fe, Cu, Zn, Rb, Sr, Y, Zr, Nb, Mo, Ru, Ag, In, Sn, Sb, La, Ce, Pr, Nd, Sm, Eu, Gd, Tb, Dy, Ho, Er, Tm, Yb, Lu, Hf, Ta, W, and Bi. That is, the first conductive region 12a may contain at least one metal selected from the group consisting of Al, Mg, Ti, Se, V, Cr, Mn, Fe, Cu, Zn, Rb, Sr, Y, Zr, Nb, Mo, Ru, Ag, In, Sn, Sb, La, Ce, Pr, Nd, Sm, Eu, Gd, Tb, Dy, Ho, Er, Tm, Yb, Lu, Hf, Ta, W, and Bi. The first conductive region 12a may be also a compound containing the first metal element. For example, the first conductive region 12a may contain a compound (silicide) containing the first metal element and silicon. Alternatively, the first conductive region 12a may contain an alloy or a solid solution containing the first metal element and another metal element (for example, the second metal element). The first conductive region 12a may contain the second metal element, or may not contain the second metal element.

In this example, the work function of the second conductive region 12b (for example, the work function of the second metal) can be set to 4.8 eV or more and 10 eV or less. More specifically, the second metal element includes, for example, at least one selected from the group consisting of Co, Ni, Se, Rh, Pd, Te, Re, Ir, Pt, and Au. That is, the second conductive region 12b may contain at least one metal selected from the group consisting of Co, Ni, Se, Rh, Pd, Te, Re, Ir, Pt, and Au. The second conductive region 12b may be also a compound containing the second metal element. For example, the second conductive region 12b may contain a compound (silicide) containing the second metal element and silicon. Alternatively, the second conductive region 12b may contain an alloy or a solid solution containing the second metal element and another metal element (for example, the first metal element). The second conductive region 12b may contain the first metal element, or may not contain the first metal element.

In the embodiment, the first conductivity-type may be the p-type. That is, the first semiconductor region 30a may be a p-type semiconductor region. When the first conductivity-type is the p-type (when the second conductivity-type is the n-type), a magnitude relationship between work functions may be opposite to that described above. That is, when the first conductivity-type is the p-type, the work function of the first conductive region 12a is larger than, for example, the work function of the second conductive region 12b. Accordingly, for example, the height of the Schottky barrier can be adjusted, and the forward voltage of the body diode can be reduced. When the first conductivity-type is the p-type, the work function of the first conductive region 12a may be, for example, 4.8 eV or more and 10 eV or less, and the work function of the second conductive region 12b may be, for example, 0.5 eV or more and 4.8 eV or less.

The semiconductor portion 30 may contain at least one selected from the group consisting of silicon (Si), a nitride semiconductor (for example, GaN), silicon carbide (SIC), and an oxide semiconductor (for example, GaO). When the semiconductor portion 30 contains silicon, an n-type impurity includes, for example, at least one selected from the group consisting of phosphorus, arsenic, and antimony. A p-type impurity includes, for example, boron.

In one example, when the semiconductor portion 30 contains silicon, the second conductive portion 12 may contain at least one selected from the group consisting of Ti, W, Mo, Ta, Zr, Al, Sn, V, Re, Os, Ir, Pt, Pd, Rh, Ru, Nb, Sr, and Hf.

The third conductive portion 13 and the fourth conductive portion 14 may contain, for example, at least one of polysilicon and a metal. The fifth conductive portion 15 contains, for example, at least one selected from the group consisting of Al, Cu, Mo, W, Ta, Co, Ru, Ti, and Pt. The first conductive portion 11 contains, for example, at least one selected from the group consisting of Al, Cu, Mo, W, Ta, Co, Ru, Ti, and Pt.

The fourth conductive portion 14 may be electrically connected to the second conductive portion 12 by a conductive portion (wiring or the like) not illustrated. Alternatively, the fourth conductive portion 14 may be electrically connectable to the second conductive portion 12. The fourth conductive portion 14 functions as, for example, a field plate. For example, local concentration of an electric field is prevented. A more stable operation is obtained.

In this example, a concentration of an impurity of the first conductivity-type in the first semiconductor region 30a is larger than a concentration of an impurity of the first conductivity-type in the third semiconductor region 30c. Accordingly, the forward voltage VF of the body diode can be reduced. For example, the thickness (the distance in the Z-axis direction) of the Schottky barrier formed at the interface between the first semiconductor region 30a and the second conductive portion 12 can be controlled by the concentration of the impurity of the first conductivity-type in the first semiconductor region 30a. When the concentration of the impurity of the first conductivity-type in the first semiconductor region 30a is relatively large, the thickness of the Schottky barrier is decreased and the tunnel current easily flows. A low forward voltage VF is easily obtained.

In this case, the concentration of the impurity of the first conductivity-type in the first semiconductor region 30a is, for example, 8×10¹⁵ atoms/cm³ or more and 8×10¹⁶ atoms/cm³ or less. The concentration of the impurity of the first conductivity-type in the third semiconductor region 30c is, for example, 8×10¹⁵ atoms/cm³ or more and 8×10¹⁶ atoms/cm³ or less. The concentration of the impurity of the first conductivity-type in the third semiconductor region 30c is, for example, a concentration in a substrate, and may be substantially constant along the Z-axis direction. For example, a boundary P between the first semiconductor region 30a and the third semiconductor region 30c may be aligned with the third conductive portion 13 in the X-axis direction.

In the embodiment, the concentration of the impurity of the first conductivity-type in the first semiconductor region 30a may not necessarily be larger than the concentration of the impurity of the first conductivity-type in the third semiconductor region 30c, and both the concentrations may be, for example, substantially the same. The work function of the first conductive region 12a may not necessarily be smaller than the work function of the second conductive region 12b, and the two work functions may be, for example, substantially the same. For example, the first conductive region 12a and the second conductive region 12b may be made of the same material, and the concentration of the impurity of the first conductivity-type in the first semiconductor region 30a may be increased. In this case, a low forward voltage VF is also easily obtained.

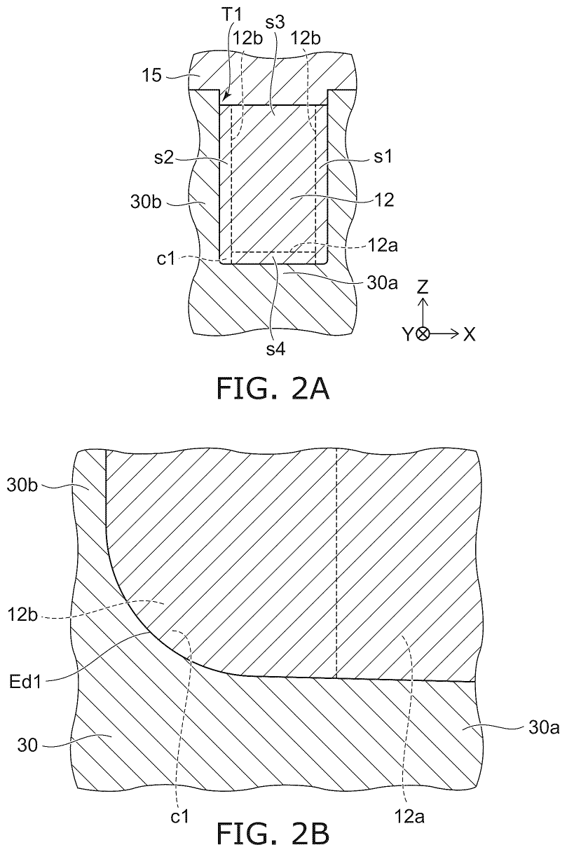

FIGS. 2A and 2B are schematic cross-sectional views illustrating the semiconductor device according to the embodiment.

FIG. 2A shows an enlarged periphery of the second conductive portion 12 of the semiconductor device 100. As shown in FIG. 2A, the second conductive portion 12 includes a first side end portion s1 and a second side end portion s2 on a side opposite thereto. The second side end portion s2 is located between the first side end portion s1 and the second semiconductor region 30b. A direction from the second side end portion s2 toward the first side end portion s1 is along the second direction (for example, the X-axis direction). The second side end portion s2 is in contact with the second semiconductor region 30b. The first side end portion s1 and the second side end portion s2 are included in the second semiconductor region 30b, and are end portions of the second conductive portion 12 in the second direction.

Further, the second conductive portion 12 includes an upper end portion s3, a lower end portion s4, and a corner portion c1. The upper end portion s3 and the lower end portion s4 are end portions of the second conductive portion 12 in the first direction. The lower end portion s4 is between the upper end portion s3 and the first semiconductor region 30a. The lower end portion s4 is in contact with the first semiconductor region 30a. The corner portion c1 is continuous from the second side end portion s2. The corner portion c1 is located below the second side end portion s2 (that is, between the second side end portion s2 and the first conductive portion 11). The corner portion c1 is a portion for connecting the second side end portion s2 and the lower end portion s4. The corner portion c1 is a portion disposed at a corner of a lower end of the trench T1. That is, the corner portion c1 is in contact with the second semiconductor region 30b.

The corner portion c1 is, for example, a part of the second conductive portion 12, and is a portion including a portion at which an angle formed by a tangent of a boundary Ed1 with the semiconductor portion 30 and the first direction is 45 degrees in a plan view including the first direction and the second direction.

In the example, the second conductive region 12b is disposed at the second side end portion s2 and the corner portion c1. That is, the second side end portion s2 and the corner portion c1 are made of the material of the second conductive region 12b having a large work function. In other words, the corner portion c1 is a part of the second conductive region 12b. The corner of the lower end of the trench T1 is covered with a material having a relatively large work function. Accordingly, concentration of the electric field at the corner can be prevented.

The first conductive region 12a is disposed at the lower end portion s4. That is, the lower end portion s4 is made of the material of the first conductive region 12a having a small work function. The bottom surface of the trench T1 excluding the corner is covered with a material having a relatively small work function.

FIG. 2B shows an enlarged periphery of the corner portion c1. In a cross section (for example, a Z-X cross section) in a plane including the first direction and the second direction as shown in FIG. 2B, a radius of curvature of the boundary Ed1 between the corner portion c1 and the semiconductor portion 30 is, for example, 1 nm or more and 100 nm or less. In this manner, since the boundary Ed1 is gently curved, for example, the concentration of the electric field at the corner portion c1 can be prevented.

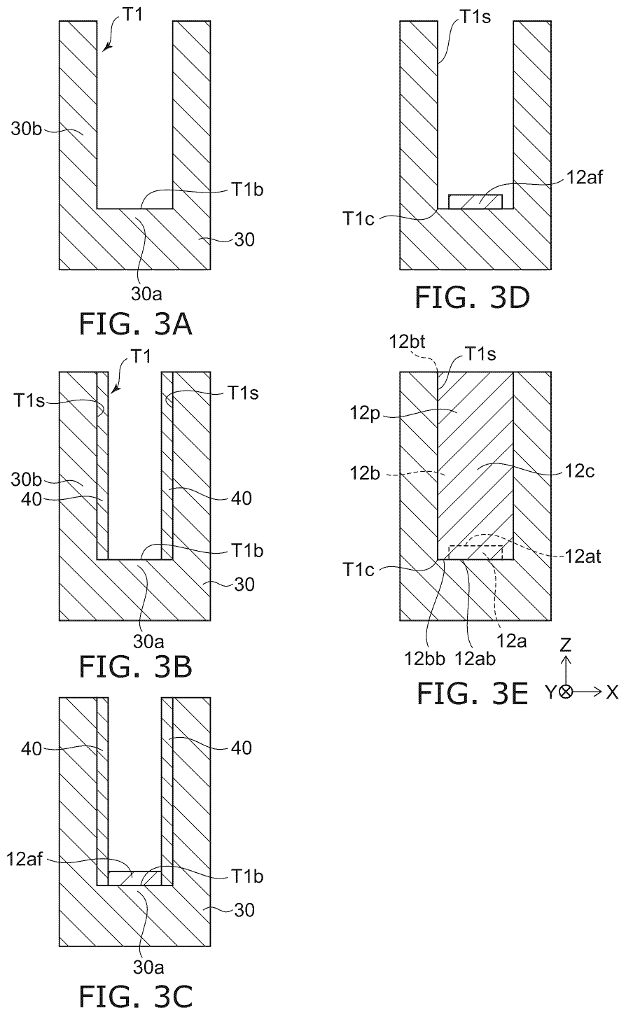

FIGS. 3A to 3E are schematic cross-sectional views illustrating a method for manufacturing the semiconductor device according to the embodiment.

FIGS. 3A to 3E show an example of a process of forming the second conductive portion 12 in a process of manufacturing the semiconductor device.

As shown in FIG. 3A, the trench T1 is formed in the semiconductor portion 30. The trench T1 can be formed by reactive ion etching. For example, a shape of the corner of the lower end of the trench can be adjusted according to an etching condition.

Thereafter, if necessary, an impurity of the first conductivity-type may be ion-implanted into a bottom surface T1b of the trench T1. Accordingly, the concentration of the impurity of the first conductivity-type in the first semiconductor region 30a can be increased.

Thereafter, as shown in FIG. 3B, a cover film 40 is formed on a side surface T1s of the trench T1. For example, silicon oxide (SiO₂) may be used in the cover film 40. The bottom surface T1b of the trench T1 is not covered with the cover film 40.

Thereafter, as shown in FIG. 3C, a conductive film 12af containing the first metal element is formed on the exposed bottom surface T1b. At least a part of the conductive film 12af is to be at least a part of the first conductive region 12a. The conductive film 12af is selectively grown on the bottom surface T1b by, for example, chemical vapor deposition (CVD). Since the side surface Tis of the trench T1 is covered with the cover film 40, the conductive film 12af is not formed on the side surface T1s of the trench T1. For example, a range in which the conductive film 12af (first conductive region 12a) is formed can be adjusted according to a thickness of the cover film 40.

Thereafter, the cover film 40 is removed as shown in FIG. 3D, and then, as shown in FIG. 3E, a conductive layer 12p containing the second metal element is formed in a manner of being embedded in the trench T1. The conductive layer 12p covers the side surface Tis of the trench T1 and a corner T1c of the trench T1. A part of the conductive layer 12p is a layer to be at least a part of the second conductive region 12b.

The second conductive region 12b formed in such a manner may not contain, for example, the first metal element. Alternatively, a concentration (atoms/cm³) of the first metal element in the second conductive region 12b may be smaller than a concentration of the first metal element in the first conductive region 12a.

For example, as shown in FIG. 3E, a position of a lower end of the first conductive region 12a may be aligned with a position of a lower end of the second conductive region 12b. In other words, a direction from a lower end portion (first lower end portion 12ab) of the first conductive region 12a toward a lower end portion (second lower end portion 12bb) of the second conductive region 12b is along the second direction (X-axis direction).

The terms “upper” and “lower” such as an upper end or a lower end are used for convenience and are unrelated to a direction of gravity or the like. The first conductive region 12a includes a first upper end portion 12at and the first lower end portion 12ab, and the first lower end portion 12ab is between the first upper end portion 12at and the first conductive portion 11.

The second conductive region 12b includes a second upper end portion 12bt and the second lower end portion 12bb, and the second lower end portion 12bb is between the second upper end portion 12bt and the first conductive portion 11.

As shown in FIG. 3E, the second conductive portion 12 includes a third conductive region 12c. The third conductive region 12c is, for example, a portion provided at a center of the trench T1. A direction from the first conductive region 12a toward the third conductive region 12c is along the first direction (Z-axis direction). A direction from the second conductive region 12b toward the third conductive region 12c is along the second direction (X-axis direction).

In this example, a part of the conductive layer 12p described above is to be the third conductive region 12c. Therefore, the third conductive region 12c contains the second metal element. The third conductive region 12c may not contain the first metal element. Alternatively, a concentration of the first metal element in the third conductive region 12c may be smaller than the concentration of the first metal element in the first conductive region 12a.

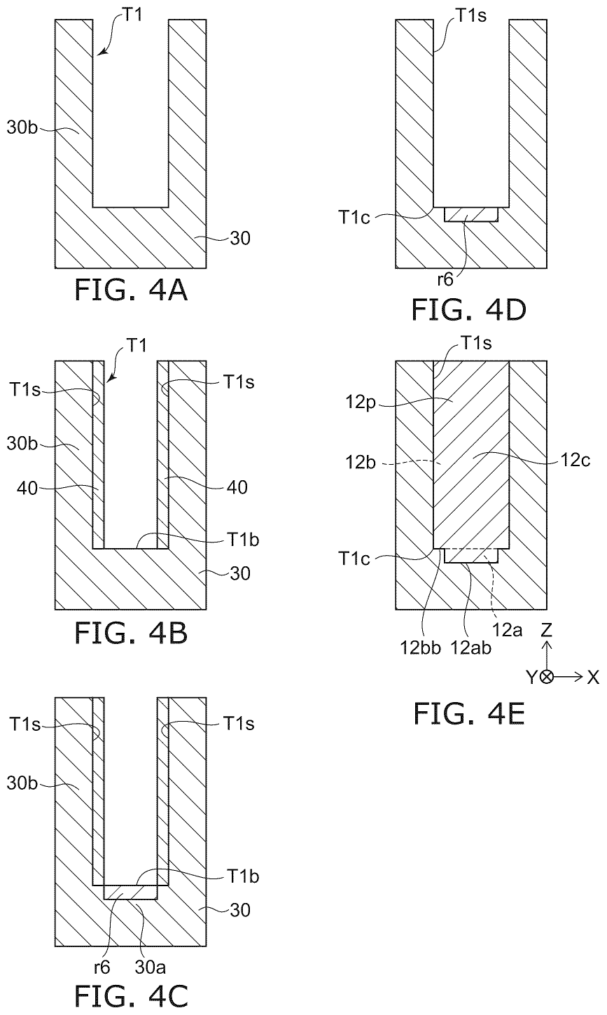

FIGS. 4A to 4E are schematic cross-sectional views illustrating the method for manufacturing the semiconductor device according to the embodiment.

FIGS. 4A to 4E show another example of the process of forming the second conductive portion 12 in the process of manufacturing the semiconductor device.

As shown in FIG. 4A, the trench T1 is formed in the semiconductor portion 30. Thereafter, as shown in FIG. 4B, the cover film 40 is formed on the side surface T1s of the trench T1. Thereafter, as shown in FIG. 4C, the first metal element is introduced into the bottom surface T1b of the trench T1. For example, the first metal element is ion-implanted into a semiconductor region r6 including the bottom surface T1b. At least a part of the semiconductor region r6 into which the first metal element is ion-implanted is to be at least a part of the first conductive region 12a. Since the side surface T1s of the trench T1 is covered with the cover film 40, the first metal element is not ion-implanted into a semiconductor region including the side surface T1s.

Thereafter, the cover film 40 is removed as shown in FIG. 4D, and then, as shown in FIG. 4E, the conductive layer 12p containing the second metal element is formed in a manner of being embedded in the trench T1.

The first conductive region 12a formed in such a manner contains, for example, the first metal element and silicon. The first conductive region 12a contains, for example, a silicide containing the first metal element.

In this example, the lower end of the first conductive region 12a may be located below the lower end of the second conductive region 12b. That is, a position of the first lower end portion 12ab of the first conductive region 12a in the Z-axis direction is between a position of the second lower end portion 12bb of the second conductive region 12b in the Z-axis direction and a position of the first conductive portion 11 in the Z-axis direction.

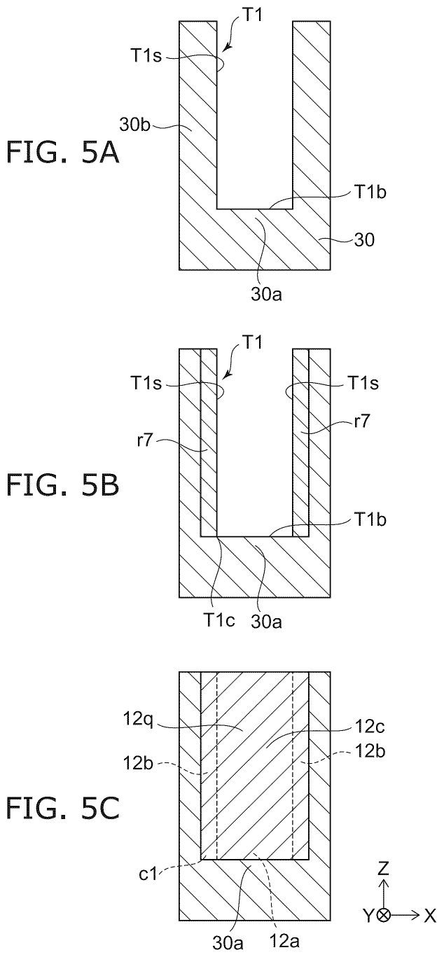

FIGS. 5A to 5C are schematic cross-sectional views illustrating the method for manufacturing the semiconductor device according to the embodiment.

FIGS. 5A to 5C show still another example of the process of forming the second conductive portion 12 in the process of manufacturing the semiconductor device.

As shown in FIG. 5A, for example, the trench T1 is formed in the semiconductor portion 30. Thereafter, as shown in FIG. 5B, the second metal element is introduced into the side surface T1s of the trench T1. For example, the second metal element is ion-implanted into a semiconductor region r7 including the side surface T1s. At least a part of the semiconductor region r7 into which the second metal element is ion-implanted is to be at least a part of the second conductive region 12b. For example, a range of the second conductive region 12b can be adjusted by adjusting an implantation angle in the ion implantation. By adjusting the implantation angle in the ion implantation, for example, the second metal element is not introduced into the bottom surface T1b of the trench T1.

Thereafter, a conductive layer 12q containing the first metal element is formed in a manner of being embedded in the trench T1. The conductive layer 12q covers the side surface T1s of the trench T1 (a surface of the semiconductor region r7) and the bottom surface T1b of the trench T1. A part of the conductive layer 12q is to be at least a part of the first conductive region 12a.

The second conductive region 12b formed in such a manner contains, for example, the second metal element and silicon. The second conductive region 12b contains, for example, a silicide containing the second metal element.

A part of the conductive layer 12q is to be the third conductive region 12c. Therefore, in this example, the third conductive region 12c contains the first metal element. The third conductive region 12c may not contain the second metal element. Alternatively, a concentration of the second metal element in the third conductive region 12c may be smaller than a concentration of the second metal element in the second conductive region 12b.

The embodiments may include the following configurations (for example, technical proposals).

### Configuration 1

A semiconductor device comprising:
a first conductive portion;
a second conductive portion, a direction from the first conductive portion toward the second conductive portion being along a first direction;
a third conductive portion, a direction from the second conductive portion toward the third conductive portion being along a second direction that intersects the first direction;
a first insulating portion including a first insulating region provided between the second conductive portion and the third conductive portion; and
a semiconductor portion of a first conductivity-type including a first semiconductor region provided between the first conductive portion and the second conductive portion, and a second semiconductor region provided between the second conductive portion and the first insulating region,
the second conductive portion including a first conductive region in Schottky junction with the first semiconductor region, and a second conductive region in Schottky junction with the second semiconductor region,
when the first conductivity-type is an n-type, a work function of the first conductive region being smaller than a work function of the second conductive region, and
when the first conductivity-type is a p-type, the work function of the first conductive region being larger than the work function of the second conductive region.

### Configuration 2

The device according to Configuration 1, wherein

the second conductive portion includes
a first side end portion,
a second side end portion located between the first side end portion and the second semiconductor region, and
a corner portion continuous from the second side end portion and located between the second side end portion and the first conductive portion, and

the corner portion is a part of the second conductive region.

### Configuration 3

The device according to Configuration 1 or 2, wherein

the second conductive portion includes
a first side end portion,
a second side end portion located between the first side end portion and the second semiconductor region, and
a corner portion continuous from the second side end portion and located between the second side end portion and the first conductive portion, and

in a cross section in a plane including the first direction and the second direction, a radius of curvature of a boundary between the corner portion and the semiconductor portion is 1 nm or more and 100 nm or less.

### Configuration 4

The device according to any one of Configurations 1 to 3, wherein
the work function of the first conductive region is 0.5 eV or more and 4.8 eV or less, and
the work function of the second conductive region is 4.8 eV or more and 10 eV or less.

### Configuration 5

The device according to any one of Configurations 1 to 4, wherein
the first conductive region contains a first metal element, and the first metal element includes at least one selected from the group consisting of Al, Mg, Ti, Se, V, Cr, Mn, Fe, Cu, Zn, Rb, Sr, Y, Zr, Nb, Mo, Ru, Ag, In, Sn, Sb, La, Ce, Pr, Nd, Sm, Eu, Gd, Tb, Dy, Ho, Er, Tm, Yb, Lu, Hf, Ta, W, and Bi, and
the second conductive region contains a second metal element, and the second metal element includes at least one selected from the group consisting of Co, Ni, Se, Rh, Pd, Te, Re, Ir, Pt, and Au.

### Configuration 6

A semiconductor device comprising:
a first conductive portion;
a second conductive portion, a direction from the first conductive portion toward the second conductive portion being along a first direction;
a third conductive portion, a direction from the second conductive portion toward the third conductive portion being along a second direction that intersects the first direction;
a first insulating portion including a first insulating region provided between the second conductive portion and the third conductive portion; and
a semiconductor portion of a first conductivity-type including a first semiconductor region provided between the first conductive portion and the second conductive portion, and a second semiconductor region provided between the second conductive portion and the third conductive portion,
the second conductive portion including a first conductive region in Schottky junction with the first semiconductor region, and a second conductive region in Schottky junction with the second semiconductor region,
the first conductive region containing a first metal element, and the first metal element including at least one selected from the group consisting of Al, Mg, Ti, Se, V, Cr, Mn, Fe, Cu, Zn, Rb, Sr, Y, Zr, Nb, Mo, Ru, Ag, In, Sn, Sb, La, Ce, Pr, Nd, Sm, Eu, Gd, Tb, Dy, Ho, Er, Tm, Yb, Lu, Hf, Ta, W, and Bi, and
the second conductive region containing a second metal element, and the second metal element including at least one selected from the group consisting of Co, Ni, Se, Rh, Pd, Te, Re, Ir, Pt, and Au.

### Configuration 7

The device according to Configuration 5 or 6, wherein
the second conductive region does not contain the first metal element, or
a concentration of the first metal element in the second conductive region is smaller than a concentration of the first metal element in the first conductive region.

### Configuration 8

The device according to any one of Configurations 5 to 7, wherein
the second conductive portion further includes a third conductive region,
a direction from the first conductive region toward the third conductive region is along the first direction, and
the third conductive region contains the second metal element.

### Configuration 9

The device according to any one of Configurations 1 to 8, wherein
the first conductive region includes a first upper end portion and a first lower end portion provided between the first upper end portion and the first conductive portion,
the second conductive region includes a second upper end portion and a second lower end portion provided between the second upper end portion and the first conductive portion, and
a direction from the first lower end portion toward the second lower end portion is along the second direction.

### Configuration 10

The device according to any one of Configurations 5 to 8, wherein
the first conductive region contains the first metal element and silicon.

### Configuration 11

The device according to any one of Configurations 1 to 8, wherein
the first conductive region includes a first upper end portion and a first lower end portion provided between the first upper end portion and the first conductive portion,
the second conductive region includes a second upper end portion and a second lower end portion provided between the second upper end portion and the first conductive portion, and
a position of the first lower end portion in the first direction is between a position of the second lower end portion in the first direction and a position of the first conductive portion in the first direction.

### Configuration 12

The device according to any one of Configurations 5 to 7, wherein
the second conductive portion further includes a third conductive region,
a direction from the first conductive region toward the third conductive region is along the first direction, and
the third conductive region contains the first metal element.

### Configuration 13

The device according to any one of Configurations 5 to 7, wherein
the second conductive region contains the second metal element and silicon.

### Configuration 14

The device according to any one of Configurations 1 to 13, wherein
the semiconductor portion further includes a third semiconductor region provided between the first conductive portion and the first semiconductor region, and
a concentration of an impurity of the first conductivity-type in the first semiconductor region is larger than a concentration of an impurity of the first conductivity-type in the third semiconductor region.

### Configuration 15

A semiconductor device comprising:
a first conductive portion;
a second conductive portion, a direction from the first conductive portion toward the second conductive portion being along a first direction;
a third conductive portion, a direction from the second conductive portion toward the third conductive portion being along a second direction that intersects the first direction;
a first insulating portion including a first insulating region provided between the second conductive portion and the third conductive portion; and
a semiconductor portion of a first conductivity-type including a first semiconductor region provided between the first conductive portion and the second conductive portion and in contact with the second conductive portion, a second semiconductor region provided between the second conductive portion and the first insulating region and in contact with the second conductive portion, and a third semiconductor region provided between the first conductive portion and the first semiconductor region,
a concentration of an impurity of the first conductivity-type in the first semiconductor region being larger than a concentration of an impurity of the first conductivity-type in the third semiconductor region.

### Configuration 16

The device according to any one of Configurations 1 to 15, wherein
the first conductive region faces the first semiconductor region in the first direction,
the second conductive region faces the second semiconductor region in the second direction,
the first semiconductor region includes a facing surface that faces the second conductive portion, and
a direction from the third conductive portion toward the facing surface is along the second direction.

### Configuration 17

The device according to any one of Configurations 1 to 16, wherein
the second semiconductor region includes a first region and a second region provided between the first region and the first conductive portion, and
a concentration of an impurity of the first conductivity-type in the first region is larger than a concentration of an impurity of the first conductivity-type in the second region.

### Configuration 18

The device according to any one of Configurations 1 to 17, further comprising:
a fourth conductive portion,
the semiconductor portion further including a third semiconductor region provided between the first conductive portion and the first semiconductor region,
a direction from the fourth conductive portion toward the third semiconductor region being along the second direction, and
the first insulating portion including a second insulating region provided between the third semiconductor region and the fourth conductive portion.

### Configuration 19

The device according to claim 18, wherein
the fourth conductive portion is electrically connected to the second conductive portion, or
the fourth conductive portion is electrically connectable to the second conductive portion.

According to the embodiment, a semiconductor device capable of reducing a forward voltage of a body diode can be provided.

In the specification, a “nitride semiconductor” includes a semiconductor having all compositions in a chemical formula BₓIn_{y}Al_{z}Ga_{1-x-y-z}N (0≤x≤1, 0≤y≤1, 0≤z≤1, and x+y+z≤1) in which the composition ratios x, y, and z are changed within corresponding ranges. Further, in the above chemical formula, those further containing Group V elements other than N (nitrogen), those further containing various elements added for controlling various physical properties such as a conductivity-type, and those further containing various elements unintentionally contained are also included in the “nitride semiconductor”.

In this specification, being “electrically connected” includes not only the case of being connected in direct contact, but also the case of being connected via another conductive member, etc.

In the specification of the application, “perpendicular” refers to not only strictly perpendicular but also includes, for example, the fluctuation due to manufacturing processes, etc. It is sufficient to be substantially perpendicular.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in semiconductor devices from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all semiconductor devices practicable by an appropriate design modification by one skilled in the art based on the semiconductor devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device comprising:
a first conductive portion;
a second conductive portion, a direction from the first conductive portion toward the second conductive portion being along a first direction;
a third conductive portion, a direction from the second conductive portion toward the third conductive portion being along a second direction that intersects the first direction;
a first insulating portion including a first insulating region provided between the second conductive portion and the third conductive portion; and
a semiconductor portion of a first conductivity-type including a first semiconductor region provided between the first conductive portion and the second conductive portion, and a second semiconductor region provided between the second conductive portion and the first insulating region,
the second conductive portion including a first conductive region in Schottky junction with the first semiconductor region, and a second conductive region in Schottky junction with the second semiconductor region,
when the first conductivity-type is an n-type, a work function of the first conductive region being smaller than a work function of the second conductive region, and
when the first conductivity-type is a p-type, the work function of the first conductive region being larger than the work function of the second conductive region.

2. The device according to claim 1, wherein
the second conductive portion includes
a first side end portion,
a second side end portion located between the first side end portion and the second semiconductor region, and
a corner portion continuous from the second side end portion and located between the second side end portion and the first conductive portion, and
the corner portion is a part of the second conductive region.

3. The device according to claim 1, wherein
the second conductive portion includes
a first side end portion,
a second side end portion located between the first side end portion and the second semiconductor region, and
a corner portion continuous from the second side end portion and located between the second side end portion and the first conductive portion, and
in a cross section in a plane including the first direction and the second direction, a radius of curvature of a boundary between the corner portion and the semiconductor portion is 1 nm or more and 100 nm or less.

4. The device according to claim 1, wherein
the work function of the first conductive region is 0.5 eV or more and 4.8 eV or less, and
the work function of the second conductive region is 4.8 eV or more and 10 eV or less.

5. The device according to claim 1, wherein
the first conductive region contains a first metal element, and the first metal element includes at least one selected from the group consisting of Al, Mg, Ti, Se, V, Cr, Mn, Fe, Cu, Zn, Rb, Sr, Y, Zr, Nb, Mo, Ru, Ag, In, Sn, Sb, La, Ce, Pr, Nd, Sm, Eu, Gd, Tb, Dy, Ho, Er, Tm, Yb, Lu, Hf, Ta, W, and Bi, and
the second conductive region contains a second metal element, and the second metal element includes at least one selected from the group consisting of Co, Ni, Se, Rh, Pd, Te, Re, Ir, Pt, and Au.

6. A semiconductor device comprising:
a first conductive portion;
a second conductive portion, a direction from the first conductive portion toward the second conductive portion being along a first direction;
a third conductive portion, a direction from the second conductive portion toward the third conductive portion being along a second direction that intersects the first direction;
a first insulating portion including a first insulating region provided between the second conductive portion and the third conductive portion; and
a semiconductor portion of a first conductivity-type including a first semiconductor region provided between the first conductive portion and the second conductive portion, and a second semiconductor region provided between the second conductive portion and the third conductive portion, the second conductive portion including a first conductive region in Schottky junction with the first semiconductor region, and a second conductive region in Schottky junction with the second semiconductor region,
the first conductive region containing a first metal element, and the first metal element including at least one selected from the group consisting of Al, Mg, Ti, Se, V, Cr, Mn, Fe, Cu, Zn, Rb, Sr, Y, Zr, Nb, Mo, Ru, Ag, In, Sn, Sb, La, Ce, Pr, Nd, Sm, Eu, Gd, Tb, Dy, Ho, Er, Tm, Yb, Lu, Hf, Ta, W, and Bi, and
the second conductive region containing a second metal element, and the second metal element including at least one selected from the group consisting of Co, Ni, Se, Rh, Pd, Te, Re, Ir, Pt, and Au.

7. The device according to claim 5, wherein
the second conductive region does not contain the first metal element, or
a concentration of the first metal element in the second conductive region is smaller than a concentration of the first metal element in the first conductive region.

8. The device according to claim 5, wherein
the second conductive portion further includes a third conductive region,
a direction from the first conductive region toward the third conductive region is along the first direction, and
the third conductive region contains the second metal element.

9. The device according to claim 1, wherein
the first conductive region includes a first upper end portion and a first lower end portion provided between the first upper end portion and the first conductive portion,
the second conductive region includes a second upper end portion and a second lower end portion provided between the second upper end portion and the first conductive portion, and
a direction from the first lower end portion toward the second lower end portion is along the second direction.

10. The device according to claim 5, wherein
the first conductive region contains the first metal element and silicon.

11. The device according to claim 1, wherein
the first conductive region includes a first upper end portion and a first lower end portion provided between the first upper end portion and the first conductive portion,
the second conductive region includes a second upper end portion and a second lower end portion provided between the second upper end portion and the first conductive portion, and
a position of the first lower end portion in the first direction is between a position of the second lower end portion in the first direction and a position of the first conductive portion in the first direction.

12. The device according to claim 5, wherein
the second conductive portion further includes a third conductive region,
a direction from the first conductive region toward the third conductive region is along the first direction, and
the third conductive region contains the first metal element.

13. The device according to claim 5, wherein
the second conductive region contains the second metal element and silicon.

14. The device according to claim 1, wherein
the semiconductor portion further includes a third semiconductor region provided between the first conductive portion and the first semiconductor region, and
a concentration of an impurity of the first conductivity-type in the first semiconductor region is larger than a concentration of an impurity of the first conductivity-type in the third semiconductor region.

15. A semiconductor device comprising:
a first conductive portion;
a second conductive portion, a direction from the first conductive portion toward the second conductive portion being along a first direction;
a third conductive portion, a direction from the second conductive portion toward the third conductive portion being along a second direction that intersects the first direction;
a first insulating portion including a first insulating region provided between the second conductive portion and the third conductive portion; and
a semiconductor portion of a first conductivity-type including a first semiconductor region provided between the first conductive portion and the second conductive portion and in contact with the second conductive portion, a second semiconductor region provided between the second conductive portion and the first insulating region and in contact with the second conductive portion, and a third semiconductor region provided between the first conductive portion and the first semiconductor region,
a concentration of an impurity of the first conductivity-type in the first semiconductor region being larger than a concentration of an impurity of the first conductivity-type in the third semiconductor region.

16. The device according to claim 1, wherein
the first conductive region faces the first semiconductor region in the first direction,
the second conductive region faces the second semiconductor region in the second direction,
the first semiconductor region includes a facing surface that faces the second conductive portion, and
a direction from the third conductive portion toward the facing surface is along the second direction.

17. The device according to claim 1, wherein
the second semiconductor region includes a first region and a second region provided between the first region and the first conductive portion, and
a concentration of an impurity of the first conductivity-type in the first region is larger than a concentration of an impurity of the first conductivity-type in the second region.

18. The device according to claim 1, further comprising:
a fourth conductive portion,
the semiconductor portion further including a third semiconductor region provided between the first conductive portion and the first semiconductor region,
a direction from the fourth conductive portion toward the third semiconductor region being along the second direction, and
the first insulating portion including a second insulating region provided between the third semiconductor region and the fourth conductive portion.

19. The device according to claim 18, wherein
the fourth conductive portion is electrically connected to the second conductive portion, or
the fourth conductive portion is electrically connectable to the second conductive portion.
